(19) United States
(12) Patent Application Publication
(10) Pub. No.: US 2021/0318732 A1
(43) Pub. Date: Oct. 14, 2021

(54) FLEXIBLE DISPLAY MOTHERBOARD AND MANUFACTURING METHOD THEREOF

(71) Applicant: Yungu (Gu'an) Technology Co., Ltd., Langfang (CN)

(72) Inventors: Xinxin YUAN, Kunshan (CN); Zhicong ZHAI, Kunshan (CN); Zhenyu ZHANG, Kunshan (CN); Yongxiang ZHAI, Kunshan (CN); Zhenzhen ZHANG, Kunshan (CN); Qinshan CAI, Kunshan (CN); Xiaojia LIU, Kunshan (CN)

(73) Assignee: Yungu (Gu'an) Technology Co., Ltd., Langfang (CN)

(21) Appl. No.: 17/355,627

(22) Filed: Jun. 23, 2021

Related U.S. Application Data
(63) Continuation of application No. PCT/CN2019/117629, filed on Nov. 12, 2019.

(30) Foreign Application Priority Data
May 23, 2019 (CN) 201910433545.4

(51) Int. Cl. G06F 1/18; G09F 9/30; G03F 7/004; H05B 3/12; H05B 3/34

(52) U.S. Cl. CPC G06F 1/184; G09F 9/301; H05B 3/34; H05B 3/12; G03F 7/0042

(57) ABSTRACT

A flexible display motherboard includes a carrier substrate, a flexible substrate and a display device disposed on the flexible substrate, where a plurality of heating resistors are arranged between the carrier substrate and the flexible substrate, and a binding force between the heating resistor and the carrier substrate is greater than a binding force between the heating resistor and the flexible substrate; the flexible substrate has an extension portion filled between adjacent heating resistors, and a molecular chain structure of the extension portion forms a hydrogen bond with the molecular chain structure of the carrier substrate; the heating resistor is used for heating the carrier substrate and the flexible substrate, so that heat generated by the heating resistor breaks the hydrogen bond.

### CROSS-REFERENCE TO RELATED APPLICATIONS

This application is a continuation of International Application No. PCT/CN2019/117629, filed on Nov. 12, 2019, which claims the benefit of priority to Chinese Patent Application No. 201910433545.4 filed on May 23, 2019 and entitled “FLEXIBLE DISPLAY MOTHERBOARD AND MANUFACTURING METHOD THEREOF”, both of the above applications are incorporated herein by reference in their entireties.

### TECHNICAL FIELD

The present application relates to the technical field of flexible display screens and particularly, to a flexible display motherboard and a manufacturing method thereof.

### BACKGROUND

In recent years, the flexible display technology has developed rapidly, and its manufacturing process and technique have also been continuously improved. Following this is the continuous increase in the size of the flexible displays and the continuous improvement in the display quality.

In the manufacturing process of a flexible display screen, a flexible substrate is required to be adhered to a hard and flat carrier substrate; then manufacture an electronic display device on the flexible substrate and complete the manufacturing of the flexible display mother board; finally, peel off the flexible substrate from the carrier substrate to obtain the flexible display screen. At present, laser peeling is often used to peel off the flexible substrate.

### SUMMARY

The present application provides a flexible display motherboard and a manufacturing method thereof, which can peel off a flexible substrate from a carrier substrate and improve a display effect of a flexible display screen.

In order to achieve the above purpose, the present application adopts following technical solutions:

an aspect of the present application provides a flexible display motherboard, including: a carrier substrate; a flexible substrate; a display device disposed on the flexible substrate; a plurality of heating resistors are arranged between the carrier substrate and the flexible substrate, and a binding force between the heating resistor and the carrier substrate is greater than that a binding force between the heating resistor and the flexible substrate; the flexible substrate has an extension portion filled between the adjacent heating resistors, and a molecular chain structure of the extension portion forms a hydrogen bond with the molecular chain structure of the carrier substrate; the heating resistor is used for heating the carrier substrate and the flexible substrate, so that heat generated by the heating resistor breaks the hydrogen bond.

In an optional implementation manner, the plurality of heating resistors are connected in turn and arranged in a circuitous manner.

In an optional implementation manner, the plurality of heating resistors are connected in turn and arranged in a spiral shape.

In an optional implementation manner, sizes of gaps formed between adjacent heating resistors are not equal.

In an optional implementation manner, a halogen group is added to a molecular chain of the flexible substrate.

In an optional implementation manner, a hydrogen bond inhibitor is added to the flexible substrate.

In an optional implementation manner, a material of the flexible substrate includes at least one of polyimide, polyethylene and polyethylene terephthalate.

In an optional implementation manner, the carrier substrate is any one of the following: a glass substrate, a quartz substrate or a silicon wafer.

In an optional implementation manner, the display device is of a multi-film layer structure.

In an optional implementation manner, the flexible substrate is made of polyimide PI.

Another aspect of the present application provides a manufacturing method of a flexible display motherboard, which includes following steps:

providing a carrier substrate; forming a plurality of heating resistors on the carrier substrate; and preparing a flexible substrate on the heating resistor, and a binding force between the heating resistor and the carrier substrate is greater than a binding force between the heating resistor and the flexible substrate; and an extension portion of the flexible substrate formed between adjacent heating resistors forms a hydrogen bond with the carrier substrate, to form the flexible display motherboard.

In an optional implementation manner, the step of forming a plurality of heating resistors on the carrier substrate includes: forming a metal conductive layer on the carrier substrate; and treating the metal conductive layer by adopting a golden photolithography process to form the plurality of heating resistors on the carrier substrate.

In an optional implementation manner, the plurality of heating resistors are connected in turn and arranged in a circuitous manner.

In an optional implementation manner, the plurality of heating resistors are connected in turn and arranged in a spiral shape.

In an optional implementation manner, sizes gaps formed between adjacent heating resistors are not equal.

Compared with the related art, the flexible display motherboard and the manufacturing method thereof provided by the present application have following advantages:

according to the flexible display motherboard and the manufacturing method thereof, a plurality of heating resistors are arranged between the carrier substrate and the flexible substrate, and the bonding force between the carrier substrate and the heating resistor is greater than the bonding force between the heating resistors and the flexible substrate; when the prepared flexible display screen is required to be peeled off from the carrier substrate, the hydrogen bond formed between the flexible substrate and the carrier substrate can be broken by the heat generated by the heating resistors, and then the flexible substrate is peeled off from the carrier substrate by virtue of an external force, with the heating resistor being left on the carrier substrate. Compared with the method of peeling off the flexible substrate through laser burning, the flexible display motherboard and the manufacturing method thereof provided by the present application adopt indirect sintering, and the energy required by such method is lower than that required for laser stripping, thus avoiding the generation of particles and black spots on the surface of the stripped flexible substrate, and improving the transparency and cleanliness of the flexible display screen obtained by separating the flexible substrate and the carrier substrate of the flexible display motherboard, thereby improving the display effect of the flexible display screen.

In addition to the technical problem solved by this application, the technical features constituting the technical solutions and beneficial effects brought by the technical features of these technical solutions described above, other technical problems solved by the flexible display motherboard and the manufacturing method thereof provided by the present application, other technical features contained in the technical solution and the beneficial effects brought by these technical features will be further explained in detail in the specific embodiments.

### BRIEF DESCRIPTION OF THE DRAWINGS

In order to explain the technical solutions in the embodiments of this application or related technologies more clearly, the following will briefly introduce the accompanying drawings required in the description of the embodiments of the present application or related technologies. Obviously, the drawings in the following description are only part of the embodiments of the present application. For those of ordinary skill in the art, other drawings can be obtained according to these drawings without paying creative labor.

FIG. 1 is a schematic structural diagram of a flexible display motherboard provided by an embodiment of the present application;

FIG. 2 is a schematic diagram of an arrangement of a heating resistor on a carrier substrate provided by an embodiment of the present application;

FIG. 3 is a schematic diagram of an arrangement of a heating resistor on a carrier substrate provided by another embodiment of the present application; and

FIG. 4 is a schematic flowchart of a manufacturing method of a flexible display motherboard provided by an embodiment of the present application.

### DETAILED DESCRIPTION OF THE EMBODIMENTS

In order to make the above objects, features and advantages of the present application more obvious and easy to understand, the technical solution in the embodiments of the present application will be described clearly and completely with reference to the accompanying drawings in the embodiments of the present application. Obviously, the described embodiments are only some embodiments of the present application, rather than all the embodiments. Based on the embodiments of the present application, all other embodiments obtained by those of ordinary skill in the art without paying creative labor belong to the scope of protection of the present application.

If laser peeling is used for peeling off the flexible substrate, a surface of the peeled flexible substrate is easy to be sintered and carbonized, resulting in particles or black spots, thus affecting a display effect of the flexible display screen.

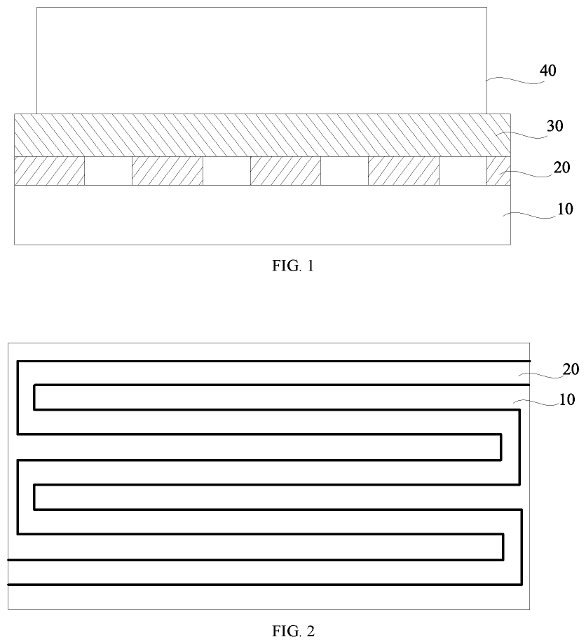

As shown in FIG. 1, an embodiment of the present application provides a flexible display motherboard, including: a carrier substrate 10, a flexible substrate 30, and a display device 40 disposed on the flexible substrate 30; a plurality of heating resistors 20 are arranged between the carrier substrate 10 and the flexible substrate 30, and a binding force between the heating resistors 20 and the carrier substrate 10 is greater than a binding force between the heating resistors 20 and the flexible substrate 30; the flexible substrate 30 has an extension portion filled between the adjacent heating resistors 20, and a molecular chain structure of the extension portion forms a hydrogen bond with a molecular chain structure of the carrier substrate 10; the heating resistor 20 is used for heating the carrier substrate 10 and the flexible substrate 30, so that heat generated by the heating resistor 20 breaks the hydrogen bond.

The flexible display screen generally includes a flexible substrate 30 and a display device 40 prepared on the flexible substrate 30; the display device 40 has a multi-film layer structure, including a driving circuit layer, a light emitting layer and an encapsulation layer disposed on the flexible substrate 30. In the process of manufacturing the flexible display screen, the carrier substrate 10 is generally selected for manufacturing the flexible display screen and forming a flexible display motherboard; the carrier substrate 10 provides a rigid support for the flexible display screen, and the flexible substrate 30 in the flexible display motherboard is required to be separated from the carrier substrate 10 after the manufacturing, so as to obtain the flexible display screen.

The carrier substrate 10 used to provide the rigid support for the flexible display screen can be made of a glass substrate or a quartz substrate with relatively good flatness, and the composing molecular chain structures of the glass substrate and the quartz substrate contain an OH-chemical bond or an O-chemical bond; the flexible substrate 30 can be made of polyimide (PI), a molecular structure of which contains a C═O,N—H & C—O—C chemical bond; when the carrier substrate 10 is in contact with the flexible substrate 30, the OH— chemical bond or the O-chemical bond in the molecular chain structure of the carrier substrate 10 can form a hydrogen bond with the C═O,N—H & C—O—C chemical bond in the molecular chain structure of the flexible substrate 30, that is, the carrier substrate 10 and the flexible substrate 30 are bonded together by the hydrogen bond.

The carrier substrate 10 is provided with a plurality of heating resistors 20, which are electrically connected with an external circuit. After the circuit is switched on, the heating resistors 20 generate heat and the generated heat is used to break the hydrogen bond formed between the carrier substrate 10 and the flexible substrate 30. The plurality of heating resistors 20 can be arranged on the carrier substrate 10 at intervals, and a gap is formed between two adjacent heating resistors 20. The flexible substrate 30 is arranged on the carrier substrate 10 where the heating resistor 20 is arranged. The flexible substrate 30 is arranged on one side of the heating resistors 20 away from the carrier substrate 10, and the side of the flexible substrate 30 facing the carrier substrate 10 is provided with a plurality of extension portions, the plurality of extension portions can be embedded in the gaps formed between two adjacent heating resistors 20 and can be in contact with the carrier substrate 10 to form hydrogen bonds. The flexible substrate 30 can be made of PI glue, which has fluidity and can fill the space formed by two adjacent heating resistors 20 and the carrier substrate 10, and the flexible substrate 30 formed by the cured PI glue can cover the heating resistors 20.

A bottom surface of the heating resistor 20 is in contact with the carrier substrate 10, which is generally made of a glass substrate and has good surface flatness, that is, the roughness of the contact surface between the heating resistor 20 and the carrier substrate 10 is small; a top surface of the heating resistor 20 is in contact with the flexible substrate 30, and the roughness of the contact surface between the heating resistor 20 and the flexible substrate 30 is greater than the roughness of the contact surface between the heating resistor 20 and the carrier substrate 10. Based on the principle that the greater the roughness of the contact surface is, the smaller the adsorption force on its surface will be, the bonding force between the heating resistors 20 and the carrier substrate 10 is greater than the bonding force between the heating resistors 20 and the flexible substrate 30.

When the carrier substrate 10 and the flexible substrate 30 in the flexible display motherboard are required to be separated, the heating resistors 20 are connected to an external circuit first, and the heat generated by the heating resistors 20 will break the hydrogen bond formed between the flexible substrate 30 and the carrier substrate 10, so that the extension portion of the flexible substrate 30 is separated from the carrier substrate 10; the heating resistors 20 are then separated from the flexible substrate 30 by virtue of a mechanical external force; since the binding force between the flexible substrate 30 and the heating resistors 20 is smaller than that between the carrier substrate 10 and the heating resistors 20, compared with the carrier substrate 10, the flexible substrate 30 can be separated from the heating resistors 20 earlier under the action of the mechanical external force, so that the heating resistors 20 can be left on the carrier substrate 10, thereby obtaining the flexible display screen.

The flexible display motherboard according to the embodiment is provided with a heating resistor 20 for heating the carrier substrate 10 and the flexible substrate 30, however, that is not taken as a limitation in the embodiment solution of the present application, a metal with a thermal conductivity may also be disposed between the carrier substrate 10 and the flexible substrate 30, and in an embodiment, a heating resistor 20 is provided between the carrier substrate 10 and the flexible substrate 30.

According to the flexible display motherboard and the manufacturing method thereof provided in the embodiment, the hydrogen bond formed between the flexible substrate 30 and the carrier substrate 10 is broken by the heat generated by the heating resistors 20, and then the flexible substrate 30 is peeled off from the carrier substrate 10 by virtue of an external force, and the heating resistors 20 are left on the carrier substrate 10. Compared with the method of peeling off the flexible substrate 30 by virtue of laser peeling, the flexible display motherboard is heated by indirect sintering, thus avoiding the generation of particles and black spots on the stripped flexible substrate 30, and improving the transparency and cleanliness of the flexible display screen obtained by separating the flexible substrate and the carrier substrate of the flexible display motherboard, thereby improving the display effect of the flexible display screen.

As shown in FIG. 2, in one embodiment, a plurality of heating resistors 20 may be connected in turn and arranged in a circuitous manner. In order to ensure uniform heating for the flexible substrate 30 and avoid the damage of its surface structure due to an excessive local temperature of the flexible substrate 30, the plurality of identical heating resistors 20 can be connected in series, so that the current flowing through each heating resistor 20 is the same and the heat generated by each heating resistor 20 is the same. In order to save an arrangement space of the heating resistors 20 and increase a heating area of the heating resistors 20, the plurality of heating resistors 20 may be arranged in a circuitous manner. The heating resistor 20 can be made of a metal resistance wire; in this way, the laying efficiency of the heating resistor 20 can be improved by circuitously arranging a whole metal resistance wire on the carrier substrate 10.

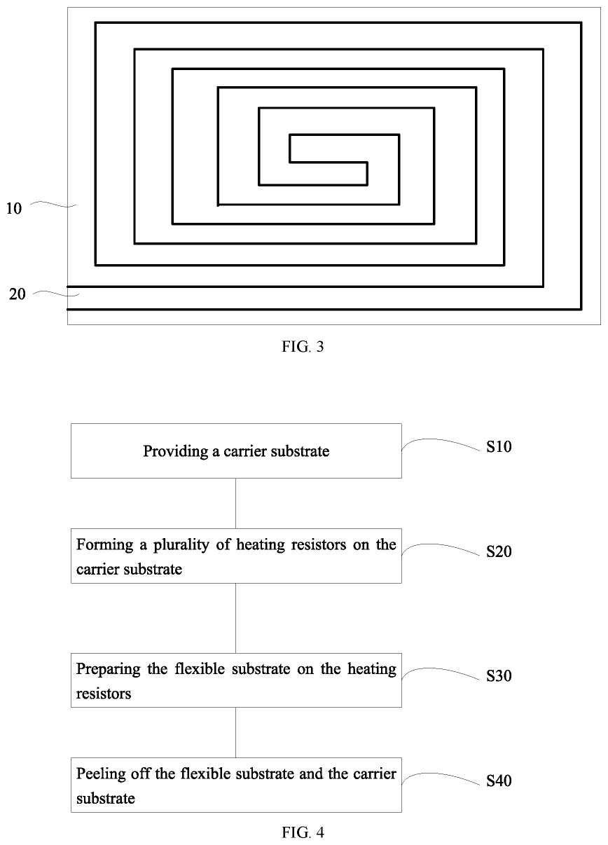

As shown in FIG. 3, in another embodiment, a plurality of heating resistors 20 may be connected in turn and arranged in a spiral shape on the carrier substrate 10, which has the same effect as the circuitous arrangement of the heating resistors 20, and will not be repeated herein. The arrangement of the plurality of heating resistors 20 provided in the embodiment is not taken as a limitation in the embodiment solution of the present application, and the plurality of heating resistors 20 may not be arranged in sequence, for example, be arranged in the manner of a comb-type, a fishbone-type, a branch-type, etc.

In the embodiment of the present application, sizes of the gaps formed between adjacent heating resistors 20 are different. A display device 40 is arranged on the flexible substrate 30 and is of a multi-film layer structure, and the stress generated in the process of its formation on the flexible substrate 30 acts on the flexible substrate 30, and the stress on the flexible substrate 30 is unevenly distributed; therefore, if the stress at the junctions of the flexible substrate 30 is transmitted to the carrier substrate 10, the binding forces (including the stress exerted by the flexible substrate 30 on the carrier substrate 10 and the hydrogen binding force between the flexible substrate 30 and the carrier substrate 10) at the junctions between the flexible substrate 30 and the carrier substrate 10 are different; in order to make the binding force at each junction of the flexible substrate 30 and the carrier substrate 10 be the same and to enhance the peeling effect between flexible substrate 30 and the carrier substrate 10, since the binding forces at each junction of the flexible substrate 30 and the carrier substrate 10 are different, the contact area between the flexible substrate 30 and the carrier substrate 10 can be adjusted by changing the size of the gap between two adjacent heating resistors 20, so that the stress exerted by the flexible substrate 30 on the carrier substrate 10 can be adjusted.

For example, increasing an arrangement density of the heating resistors 20 at a position where the flexible substrate 30 exerts a greater stress on the carrier substrate 10 can reduce the size of the gap between two adjacent heating resistors 20, thereby reducing the contact area between the flexible substrate 30 and the carrier substrate 10 at this position, reducing the stress transmitted from the flexible substrate 30 to the carrier substrate 10, and making the stress to be overcome during the peeling process at the junctions between the flexible substrate 30 and the carrier substrate 10 consistent. After the hydrogen bond between the flexible substrate 30 and the carrier substrate 10 is broken, the flexible substrate 30 can be separated from the carrier substrate 10 under the same mechanical external force.

In an optional implementation manner, halogen groups are added to a molecular chain of the flexible substrate 30. The flexible substrate 30 is often made of polyimide, so that the molecular chain structure of the flexible substrate 30 is modified, and the halogen groups such as —F and -cl are added to its molecular chain structure; the adding of the halogen groups to polyimide makes it easy to preferentially form intramolecular hydrogen bonds in the flexible substrate 30, which can reduce the number of hydrogen bonds formed between the flexible substrate 30 and the carrier substrate 10, thereby reducing the hydrogen binding force between the flexible substrate 30 and the carrier substrate 10. When the flexible substrate 30 and the carrier substrate 10 are required to be peeled off, the reduction in the heat required to break the hydrogen bond would be beneficial for peeling off the carrier substrate 10 from the flexible substrate 30, and saving the electric energy at the same time.

In the embodiment, a hydrogen bond inhibitor can also be doped into polyimide used for forming the flexible substrate 30, the hydrogen bond inhibitor can reduce the number of hydrogen bonds generated between molecules of the flexible substrate 30 and the carrier substrate 10, thereby reducing the hydrogen binding force between the flexible substrate 30 and the carrier substrate 10; when the flexible substrate 30 and the carrier substrate 10 are required to be peeled off, the heat for breaking hydrogen bonds is reduced, and the peeling efficiency and effect of the carrier substrate 10 and the flexible substrate 30 are improved.

In the embodiment, in addition to polyimide materials, the flexible substrate 30 can also be made of polyethylene and polyethylene terephthalate materials, so that flexible displays with different flexible substrates can be formed. Meanwhile, the hydrogen binding forces generated between the flexible substrate 30 made of different materials and the carrier substrate 10 are different, so that different stripping temperatures can be selected, and the flexible substrate 30 with the best benefit can be selected.

As shown in FIG. 4, an embodiment of the present application provides a manufacturing method of a flexible display screen, which includes following steps:

Step S10, providing a carrier substrate 10; the carrier substrate 10 may be any one of the following: a glass substrate, a quartz substrate or a silicon wafer. In an embodiment, the carrier substrate is a glass substrate.

Step S20: forming a plurality of heating resistors 20 on the carrier substrate 10; a metal conductive layer is formed on a surface of the carrier substrate 10 through a sputtering process, and the metal conductive layer is patterned to form a plurality of heating resistors 20, and the heat generated when a current passes through the heating resistors 20 is used to heat the flexible substrate 30 and the carrier substrate 10. In addition, there is a gap between two adjacent heating resistors 20, so that the current flows along the forming direction of the heating resistors 20. By reasonably arranging the plurality of heating resistors 20 on the carrier substrate 10, the flexible substrate 30 and the carrier substrate 10 can be uniformly heated.

In the embodiment, a metal conductive layer is formed on the carrier substrate 10, and the metal conductive layer is patterned through a golden photolithography process, and the processing process is as follows: coating a layer of golden photoresist on a surface of the metal conductive layer; exposing and developing the golden photoresist according to a preset pattern; forming a corresponding preset pattern on the surface of the golden photoresist; then etching, based on the golden photoresist, the metal conductive layer according to a preset pattern (a circuit), so that the metal conductive layer is etched to form a plurality of heating resistors 20; arranging the plurality of heating resistors 20 according to a preset pattern; and then peeling off the golden photoresist from the metal conductive layer.

S30: preparing the flexible substrate 30 on the heating resistors 20, where the flexible substrate 30 is usually made of PI glue which has fluidity; filling the gap formed between adjacent heating resistors 20 with the PI glue and covering the surface of the heating resistors 20, where a coating thickness of the PI glue on top of the heating resistors 20 can be selected according to a thickness of the flexible substrate 30; the flexible substrate 30 is produced after the curing of the PI glue, and an extension portion is formed on one side of the flexible substrate 30 facing the carrier substrate 10, where the extension portion is located in the gap formed between two adjacent heating resistors 20, and the end of the extension portion abuts against the carrier substrate 10 to form hydrogen bonds.

One side of the heating resistor 20 is in contact with the carrier substrate 10 to form a first bonding force, and the other side of the heating resistor 20 is in contact with the flexible substrate 30 to form a second bonding force. The roughness of the contact surface between the carrier substrate 10 and the heating resistor 20 is smaller than the roughness of the contact surface between the flexible substrate 30 and the carrier substrate 10, therefore, the first bonding force is greater than the second bonding force.

After obtaining the flexible display motherboard through the above steps, a flexible display screen can be further obtained.

S40: peeling off the flexible substrate 30 and the carrier substrate 10 in the flexible display motherboard; making a circuit where the heating resistors 20 are located active, then a current passes through the heating resistors 20 and generates heat for heating the flexible substrate 30 and the carrier substrate 10, and the generated heat breaks the hydrogen bond between the carrier substrate 10 and the flexible substrate 30, so that the extension portion is separated from the carrier substrate 10; peeling off the flexible substrate 30 from the heating resistors 20 under the action of a mechanical external force, with the heating resistor 20 being left on the carrier substrate 10, thereby obtaining a flexible display screen.

Finally, it should be noted that the above embodiments are only used to illustrate the technical solutions of the present application, and do not constitute a limitation; although the present application has been described in detail with reference to the foregoing embodiments, those of ordinary skill in the art should understand that they can still modify the technical solutions described in the foregoing embodiments, or equivalently replace some or all of the technical features; and these modifications or substitutions do not make the essence of the corresponding technical solutions deviate from the scope of the technical solutions of the embodiments of the present application.

What is claimed is:

1. A flexible display motherboard, comprising:
a carrier substrate;
a flexible substrate;
a display device disposed on the flexible substrate;
wherein a plurality of heating resistors are arranged between the carrier substrate and the flexible substrate, and a binding force between the heating resistor and the carrier substrate is greater than a binding force between the heating resistor and the flexible substrate;
the flexible substrate has an extension portion filled between adjacent heating resistors, and a molecular chain structure of the extension portion forms a hydrogen bond with a molecular chain structure of the carrier substrate; and
the plurality of heating resistors are used for heating the carrier substrate and the flexible substrate to make heat generated by the heating resistor break the hydrogen bond.

2. The flexible display motherboard of claim 1, wherein the plurality of heating resistors are connected in turn and arranged in a circuitous shape.

3. The flexible display motherboard of claim 1, wherein the plurality of heating resistors are connected in turn and arranged in a spiral shape.

4. The flexible display motherboard of claim 1, wherein sizes of gaps formed between the adjacent heating resistors are not equal.

5. The flexible display motherboard of claim 1, wherein a halogen group is added to a molecular chain of the flexible substrate.

6. The flexible display motherboard of claim 1, wherein a hydrogen bond inhibitor is added to the flexible substrate.

7. The flexible display motherboard of claim 5, wherein a material of the flexible substrate comprises at least one of polyimide, polyethylene and polyethylene terephthalate.

8. The flexible display motherboard of claim 1, wherein the carrier substrate is one of the following: a glass substrate, a quartz substrate or a silicon wafer.

9. The flexible display motherboard of claim 1, wherein the display device is of a multi-film layer structure.

10. The flexible display motherboard of claim 1, wherein the flexible substrate is made of polyimide (PI).

11. A manufacturing method of a flexible display motherboard, comprising:
providing a carrier substrate;
forming a plurality of heating resistors on the carrier substrate; and
preparing a flexible substrate on the heating resistors, wherein a binding force between the heating resistor and the carrier substrate is greater than a binding force between the heating resistor and the flexible substrate; and an extension portion of the flexible substrate formed between adjacent heating resistors forms a hydrogen bond with the carrier substrate, to form the flexible display motherboard.

12. The manufacturing method of the flexible display motherboard of claim 11, wherein,
the forming of the plurality of heating resistors on the carrier substrate comprises:
forming a metal conductive layer on the carrier substrate; and
treating the metal conductive layer by adopting a golden photolithography process to form the plurality of heating resistors on the carrier substrate.

13. The manufacturing method of the flexible display motherboard of claim 11, wherein the plurality of heating resistors are connected in turn and arranged in a circuitous shape.

14. The manufacturing method of the flexible display motherboard of claim 11, wherein the plurality of heating resistors are connected in turn and arranged in a spiral shape.

15. The manufacturing method of the flexible display motherboard of claim 11, wherein sizes of gaps formed between adjacent heating resistors are not equal.

16. The flexible display motherboard of claim 11, wherein a halogen group is added to a molecular chain of the flexible substrate.

17. The flexible display motherboard of claim 11, wherein a hydrogen bond inhibitor is added to the flexible substrate.

18. The flexible display motherboard of claim 16, wherein a material of the flexible substrate comprises at least one of polyimide, polyethylene and polyethylene terephthalate.

19. The flexible display motherboard of claim 11, wherein the carrier substrate is any one of the following: a glass substrate, a quartz substrate or a silicon wafer.
